(19) United States
(12) Patent Application Publication
(10) Pub. No.: US 2026/0368953 A1
(43) Pub. Date: Nov. 19, 2026

(54) CLADDING COORDINATION TOOL AND METHOD FOR SELECTING COLOR OF CLADDING

(71) Applicant: SEKISUI HOUSE, LTD., Osaka-shi, Osaka (JP)

(72) Inventors: Fumito SUZUKI, Osaka-shi (JP); Jin HAYASHI, Osaka-shi (JP); Dai HASHIMOTO, Osaka-shi (JP); Mayumi NAKANISHI, Osaka-shi (JP); Ryuichiro YASUNAGA, Osaka-shi (JP)

(21) Appl. No.: 19/133,588

(22) PCT Filed: Aug. 23, 2023
(86) PCT No.: PCT/JP2023/030353

§ 371 Date: May 28, 2025

(30) Foreign Application Priority Data
Dec. 2, 2022 (JP) 2022-193664

(51) Int. Cl. G06T 11/10

(52) U.S. Cl. CPC G06T 11/10

(57) ABSTRACT

A cladding coordination tool (10) is a tool for selecting the color of cladding for a building. The cladding coordination tool (10) has: a plurality of first display units (11) constituting a first line-up of chromatic colors; and a plurality of second display units (12) constituting a second line-up of achromatic colors. The plurality of first display units (11) display mutually different colors. The plurality of second display units (12) display mutually different colors. The achromatic colors include colors, of the chromatic colors, with a saturation of less than 0.8. The saturation of the colors of the first display units (11) is in a range of 0.8 or more and less than 3.5.

### TECHNICAL FIELD

The present disclosure relates to an exterior material coordination tool for coordinating a color of an exterior material of a building, and a method for selecting a color of an exterior material.

### BACKGROUND ART

The exterior color of a building is typically determined taking into consideration the local landscape.

Patent Literature 1 describes an example of a technique that determines an exterior color of a building using a color chart for buildings. This technique selects color information based on the landscape around the building. Then, a guidance region that matches the selected color information is determined within a predetermined range of the color chart for buildings. Subsequently, the exterior color of the target building is determined in the guidance region.

### CITATION LIST

### Patent Literature

Patent Literature 1: Japanese Laid-Open Patent Publication No. 2003-222557

### SUMMARY OF INVENTION

### Technical Problem

In recent years, there is a demand to extend the life spans of buildings for various reasons, such as increasing longevity of people, achievement of sustainable society, and the like. For example, housing designed for long-term use has been promoted. For the same reasons mentioned above, there is also a demand that the external appearance of a building is designed on the premise of long-term use of the building. Accordingly, an exterior material coordination tool and a method for selecting a color of an exterior material are provided to create a design suitable for long-term use of a building.

### Solution to Problem

(1) An exterior material coordination tool that solves the above problem is for selecting a color of an exterior material of a building. The exterior material coordination tool includes first display portions constituting a first lineup of chromatic colors, and second display portions constituting a second lineup of achromatic colors. The first display portions show colors different from each other. The second display portions show colors different from each other. The achromatic colors include chromatic colors having chroma of less than 0.8. Chroma of the colors of the first display portions is in a range of 0.8 or greater and less than 3.5.

With this configuration, each of the colors shown by the first display portions and the second display portions in the exterior material coordination tool is either an achromatic color or a chromatic color with low chroma. Achromatic colors and low chroma colors are commonly found in natural objects, such as wood or stone, and are thus in harmony with the scenery of a certain country (in an example, Japan) and unlikely to become awkward or old regardless of era or trends. In this manner, a color suitable for long-term use of the building is proposed as the color of the exterior material.

(2) In the exterior material coordination tool according to (1), the chroma of the colors of the first display portions is in a range of 1.0 or greater and less than 1.5.

With this configuration, since the chroma of the first display portions is less than 1.5, the colors of the first display portions aesthetically enhance the natural colors (hereinafter, “building surrounding natural colors”) around the building, such as green of the greenery, red or yellow of autumn leaves, or the like. The building surrounding natural colors are the colors that have always existed regardless of eras. The colors of the first display portions aesthetically enhance such building surrounding natural colors. In this manner, a color suitable for long-term use of the building is proposed as the color of the exterior material.

The second display portions are achromatic. Achromatic colors aesthetically enhance the building surrounding natural colors. With the exterior material coordination tool including the low chromatic first display portions and the achromatic second display portions, a color suitable for long-term use of the building can be proposed as the color of the exterior material from the chromatic colors and the achromatic colors.

(3) In the exterior material coordination tool according to (2), hue of the colors of the first display portions is in a range of 7.5 YR to 10 YR, inclusive, and 1.0 Y or greater and less than 5.0 Y in the Munsell color system.

Such colors of the first display portions aesthetically enhance the building surrounding natural colors, and are in harmony with the colors used in exterior materials of buildings that remain in a certain country across different eras. It can be said that buildings that remain in a certain country across different eras have universal colors that blend into the landscape of the country. In this manner, a color suitable for long-term use of the building is proposed as the color of the exterior material. In the present specification, the term “certain country” means a country in which the present invention is practiced. In an example, “certain country” means Japan.

(4) In the exterior material coordination tool according to any one of (1) to (3), rightness of the colors of the first display portions and brightness of the colors of the second display portions are in a range of 3.0 or greater and less than 9.0.

Natural colors of mountains, rivers, valleys, or oceans do not usually contain colors having a brightness that is lower than 3.0 in daylight. Further, natural colors of mountains, rivers, valleys, or oceans do not usually contain colors having a brightness that is higher than 9.0 in daylight. Since the brightness of the colors of the first display portions and the brightness of the colors of the second display portions are 3.0 or greater and less than 9.0, when the colors of the first display portions or the colors of the second display portion are adopted for the exterior material of the building, there will not be discordance between the natural colors and the colors of the first display portions and the colors of the second display portions. With this configuration, a color suitable for long-term use of the building is proposed as the color of the exterior material.

(5) In the exterior material coordination tool according to (4), the brightness of the colors of the first display portions and the brightness of the colors of the second display portions are in a range of 3.0 to 5.0, inclusive, or in a range of 6.0 or greater and less than 9.0.

In many cases, greenery is planted around the building. Also, the building is built where vegetation can be seen, such as trees in mountains, crops in fields, trees along streets, trees and grass in parks, or the like. A typical value of the brightness of the greenery or the like (greenery and vegetation around building) is approximately greater than 5.0 and less than 6.0 throughout the four seasons. When the brightness of the building overlaps the brightness of the greenery or the like, even if the hue of the building differs from the hue of the greenery or the like, the building and the greenery or the like have the same color tone. Accordingly, the building and the greenery or the like as a whole appear to lack variation. In this respect, the above configuration sets the first display portions and the second display portions to have different brightness from the greenery or the like. Therefore, in a case in which the greenery or the like is arranged around the building, an appropriate color can be suggested such that the overall appearance including the building and the greenery or the like will not be monotonous.

(6) In the exterior material coordination tool according to any one of (1) to (5), the first display portions and the second display portions each belong to any one of multiple groups divided by brightness. A difference in brightness between any one of the first display portions and the second display portions that belongs to one of the groups and any one of the first display portions and the second display portions that belongs to another one of the groups is 1 or greater.

With this configuration, when selecting two colors from the exterior material coordination tool, two colors having a brightness difference of 1 or greater may be easily selected. For example, two distinctly different colors may be readily selected when designing a residential area of multiple buildings or when using two colors for the external appearance of a single building.

(7) In the exterior material coordination tool according to any one of (1) to (6), the first display portions and the second display portions are arranged on a base board. With this configuration, the exterior material coordination tool may be easily carried.

(8) In the exterior material coordination tool according to any one of (1) to (6), the first display portions and the second display portions are shown on a display screen of an electronic device. With this configuration, as compared to when the first display portion and the second display portion are printed, the colors will not be degraded by ultraviolet rays.

(9) A method that solves the above problem is for selecting a color of an exterior material of a building using the exterior material coordination tool according to any one of (1) to (8). The method includes a first step of setting a base color based on a color of a region where the building is to be constructed, and a second step of selecting a color of the exterior material from the first lineup or the second lineup, the color having a brightness difference of 1.5 or greater from the base color. The color of the region is a color of a building material produced in the region or a color of a building material used for a building that serves as a landmark of the region.

With this configuration, when a color specific to the region where the building is to be constructed is adopted for the building, another color suitable for long-term use of the building can be selected as the color of the exterior material without obscuring the color of the region.

(10) A method that solves the above problem is for selecting a color of an exterior material of a building using the exterior material coordination tool according to any one of (1) to (8). The method includes a first step of setting a greenery coverage ratio in a perspective drawing of an external appearance of the building, and a second step of selecting a color of the exterior material from the first lineup or the second lineup with reference to a color selection chart based on the greenery coverage ratio. The color selection chart is a chart in which brightness of the color increases as the greenery coverage ratio decreases. With this configuration, the color of the exterior material of the building may be selected based on the greenery coverage ratio. This maintains the brightness of the entire building within the appropriate range.

(11) A method that solves the above problem is for selecting a color of an exterior material of a building using the exterior material coordination tool according to any one of (1) to (8). The method includes a first step of setting an orientation of a facade of the building, and a second step of selecting a color of the exterior material from the first lineup or the second lineup with reference to a color selection table based on the orientation of the facade. In the color selection table, the facade facing east is associated with the second lineup, the facade facing south is associated with the first lineup and the second lineup, the facade facing west is associated with the first lineup, and the facade facing north is associated with the first lineup and the second lineup. With this configuration, colors that enhance the aesthetic appearance of the building at the time of day when the sun shines on the building may be proposed.

(12) In the method according to (11), when the orientation of the facade of the building is set to north in the northern hemisphere in the first step, and two colors are adopted for the facade facing north, or when the orientation of the facade of the building is set to south in the southern hemisphere in the first step, and two colors are adopted for the facade facing south, the second step includes selecting two colors from the first lineup and the second lineup so that a brightness difference is 2.0 or greater.

In the northern hemisphere, a north-facing facade is in the shade during the day. Accordingly, when two colors are used for the north-facing facade, it may be difficult to recognize the difference in the two colors. In this respect, the above configuration proposes two distinctly different colors for the north-facing facade. In the southern hemisphere, “north-facing” is replaced by “south-facing”.

### Advantageous Effects of Invention

The exterior material coordination tool and the method for selecting a color of an exterior material according to the present disclosure contribute to a design suitable for long-term use of a building.

### BRIEF DESCRIPTION OF DRAWINGS

FIG. 1 is a schematic diagram of an exterior material coordination tool in accordance with a first embodiment.

FIG. 2 is a tone diagram used in color analysis of an image.

FIG. 3 is an image scale used in color analysis of an image.

FIG. 4 is a flowchart illustrating a method for selecting a color of an exterior material of a building in accordance with a second embodiment.

FIG. 5 is a diagram showing a perspective drawing of an external appearance of a building in which a base color is set.

FIG. 6 is a schematic diagram of the exterior material coordination tool in which a recommended range of colors is indicated.

FIG. 7 is a flowchart illustrating a method for selecting a color of an exterior material of a building in accordance with a third embodiment.

FIG. 8 is a diagram showing a perspective drawing of an external appearance of a building including a greenery range.

FIG. 9 is a diagram showing a color selection chart.

FIG. 10 is a flowchart illustrating a method for selecting a color of an exterior material of a building in accordance with a fourth embodiment.

FIG. 11 is a diagram showing a color selection table.

FIG. 12 is a diagram showing a facade of a building facing north.

FIG. 13 is a schematic diagram of a residential area in accordance with a fifth embodiment.

### DESCRIPTION OF EMBODIMENTS

### First Embodiment

### Exterior Material Coordinate Tool

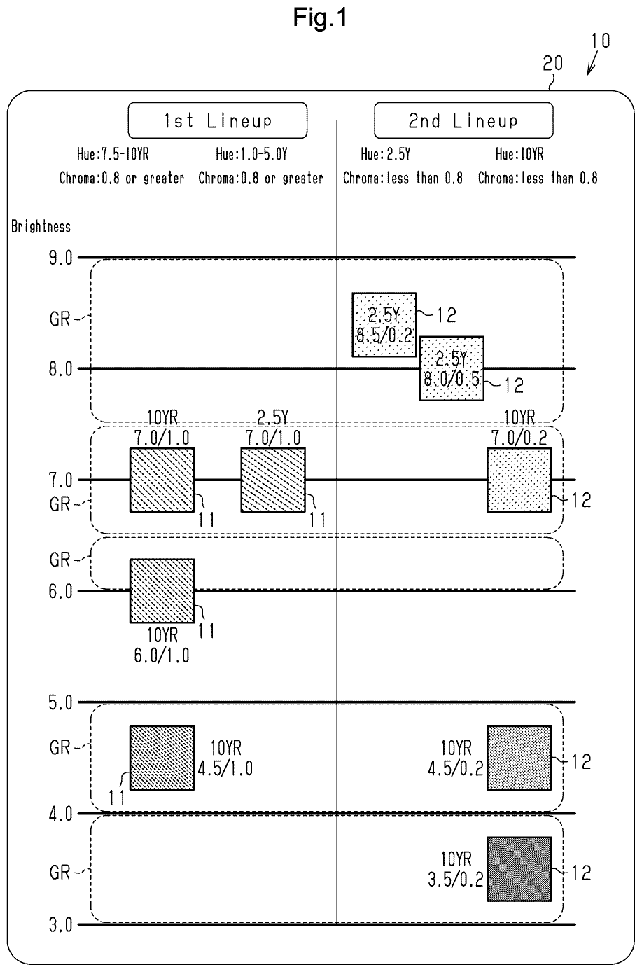

An exterior material coordination tool 10 will now be described with reference to FIGS. 1 to 3. In FIG. 1, parameter A/B appended to each of a plurality of first display portions and a plurality of second display portions 12 indicates “brightness/chroma”.

The exterior material coordination tool 10 assists in selecting a color of an exterior material 7 of a building 1 in the design of the building 1. A designer designs the building 1 based on the preferences of a client related to the design. The designer also proposes the design of the building 1 in accordance with regional regulations related to the building 1. In recent years, there is an aspiration for universal designs, timeless designs, or designs that are in harmony with the surroundings of the building 1 from perspectives of sustainability and prolongation of the life span of the building 1. The exterior material coordination tool 10 assists in creating a design that takes into consideration the perspective of prolongation of the life span of the building 1. The exterior material coordination tool 10 assists in selection of a color by the designer when creating a design that takes into consideration the perspective of prolongation of the life span of the building 1. The exterior material coordination tool 10 is prepared on the premise that the building 1 is constructed in a certain country.

The exterior material coordination tool 10 is a tool for selecting the color of the exterior material 7 of the building 1.

The exterior material 7 includes an exterior wall material that forms an outer surface of an outer wall 6, a member that forms a retaining wall, and an exterior wall material that forms an outer surface of a perimeter wall. The exterior wall material of the outer wall 6 or the perimeter wall includes tiles, exterior paints, exterior sheets, stone materials, concrete materials, synthetic resin panels, metal panels, ceramic plates, ceramic members, and wood materials. The exterior material coordination tool 10 is prepared for each type of the exterior material 7. The exterior material coordination tool 10 for an exterior wall material differs from the exterior material coordination tool 10 for a retaining wall. Further, the exterior material coordination tool 10 for an exterior wall material may be separately prepared for each material type. For example, the exterior material coordination tool 10 for an exterior wall material made of ceramic plate is prepared separately from the exterior material coordination tool 10 for an exterior wall material made of stone. Furthermore, there may be a common exterior material coordination tool 10 for an exterior wall material that is used regardless of the material type.

The exterior material coordination tool 10 has a first lineup of chromatic colors and a second lineup of achromatic colors. The first lineup of chromatic colors includes a plurality of first display portions 11. The first display portions 11 show colors different from each other. The second lineup of achromatic colors includes a plurality of second display portions 12. The second display portions 12 show colors different from each other.

In the present disclosure, an achromatic color includes a color having a hue that is difficult to be visually determined. An example of the achromatic color is gray that may be perceived as slightly bluish. In the present embodiment, an achromatic color includes a chromatic color having chroma of less than 0.8.

The first display portions 11 and the second display portions 12 are arranged on a base board 20. The base board 20 is formed from a plate or a sheet.

The first display portions 11 and the second display portions 12 show colors. In an example, the first display portions 11 and the second display portions 12 are rectangular sheets or circular sheets each having a front surface painted in a predetermined color. The first display portions 11 and the second display portions 12 may each be formed by a photograph of a surface of a predetermined building material. The first display portions 11 and the second display portions 12 may each be formed by a sample of an exterior material. The first display portions 11 and the second display portions 12 may each be formed by a model of a sample of an exterior material.

The first display portions 11 and the second display portions 12 are each assigned with a color symbol that allows for recognition of the color shown. The color symbol includes values of hue, brightness, and chroma. The color symbol is indicated near a corresponding one of the first display portions 11 and the second display portions 12. An example of the color symbol is a Munsell value. A Munsell value can be converted from other types of color symbol. For example, a Munsell value may be obtained by converting an RGB value, a CMYK value, or a HEX value using a predetermined calculation formula.

In a case in which the first display portions 11 and second display portions 12 are formed through printing using an electronic computer and a printer, the color symbols of the colors of first display portions 11 and second display portions 12 may be identified based on a color parameter (for example, RGB value) in the electronic computer.

In a case in which the first display portions 11 and the second display portions 12 are formed by samples of exterior wall materials, the color symbols of the colors of the first display portions 11 and the second display portions 12 are identified using a color chart. In a case in which the first display portions 11 and the second display portions 12 are formed by samples of exterior wall materials, the color symbols may be identified based on a color parameter (for example, RGB value) of pixel data of digital images of the samples of exterior wall materials.

### First Display Portion

The chroma of the colors of the first display portions 11 is in a range of 0.8 or greater and less than 3.5. Preferably, the chroma of the colors of first display portions 11 is in a range of 1.0 or greater and less than 1.5. In other words, the exterior material coordination tool 10 does not show chromatic colors having chroma of 3.5 or greater. The exterior material coordination tool 10 only shows chromatic colors having relatively low chroma.

The hue of the colors of the first display portions 11 is in a range of 7.5 YR to 10 YR, inclusive, and 1.0 Y or greater and less than 5.0 Y in the Munsell color system (hereinafter, the specific color range). The brightness of the colors of the first display portions 11 is in a range of 3.0 or greater and less than 9.0. In an example, the brightness of the colors of the first display portions 11 is in a range of 3.0 to 5.0, inclusive, or in a range of 6.0 or greater and less than 9.0.

### Second Display Portion

The brightness of the colors of the second display portions 12 is in a range of 3.0 or greater and less than 9.0. In an example, the brightness of the colors of the second display portions 12 is in a range of 3.0 to 5.0, inclusive, or in a range of 6.0 or greater and less than 9.0.

### Groups

The first display portions 11 and the second display portions 12 each belong to any one of multiple groups GR divided by brightness. A difference in brightness between any one of the first display portions 11 and the second display portions 12 that belongs to one group GR and any one of the first display portions 11 and the second display portions 12 that belongs to another group GR is 1 or greater. Therefore, in the exterior material coordination tool 10, when two different groups GR are selected and a single color is selected from each of the two groups GR, the difference in brightness of the two selected colors is 1 or greater.

The colors of the first lineup shown in the exterior material coordination tool 10 are in the same color tone. Therefore, if selection is simply made by preference, two selected colors may be indistinguishably similar. When the two indistinguishably similar colors are used in the building 1, the external appearance of the building 1 may be diminished. Accordingly, a tool that groups multiple display portions to allow for selection of colors having a brightness difference of 1 or greater is useful when selecting multiple colors.

### Color Analysis of Scenery and Buildings in Countries

The color range of the first display portions 11 and the color range of the second display portions 12 described above are supported by color analysis of buildings 1 and scenery (hereinafter, the selected buildings and the selected scenery) selected in a certain country (in an example, Japan). The selected buildings and the selected scenery include buildings 1 and scenery in a district (in Japan, “Preservation District for Group of Traditional Buildings”) in which a group of traditional buildings selected by a predetermined organization in the country are preserved, as well as scenery of cultural landscapes (in Japan, “Important Cultural Landscapes”) selected by a predetermined organization in the country. Color analysis of the selected buildings and the selected scenery are performed using images of the selected buildings and the selected scenery. Examples of color analysis include analysis of appearance ratios of colors in a Munsell table or the HUE & TONE system and analysis of appearance ratios of tones in an image. The HUE & TONE system is a color analysis system developed by NIPPON COLOR & DESIGN RESEARCH INSTITUTE INC. (hereafter abbreviated as “NCD”).

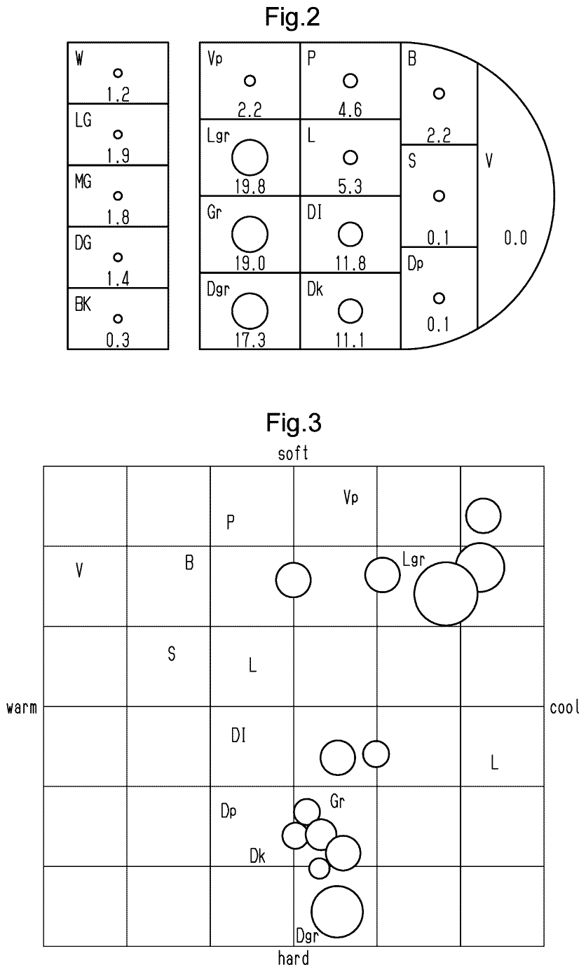

An example of analysis of appearance ratios of the colors in an image will now be described with reference to FIGS. 2 and 3. In an example, in color analysis, the color of each pixel in an image of a building or scenery is identified. The color of each pixel is specified as one of 1093 colors in the HUE & TONE system. Specifically, the color of each pixel is determined as follows. First, a color closest to the color of each pixel is selected from 1093 colors in the HUE & TONE system. Then, the selected color is specified as the color of the pixel. In this manner, an image is analyzed using 1093 colors. Subsequently, the frequency of appearance of each color in the image is calculated. The frequency of appearance of a color is defined as the quantity of pixels showing that color. The appearance ratio of a color is defined as (color appearance frequency)/(total quantity of pixels in image). Such color analysis by statistical processing is visualized in a tone diagram (refer to FIG. 2) or an image scale (refer to FIG. 3). The tone diagram refers to a tone diagram of the HUE & TONE system of NCD. The image scale is a color image analysis system developed by NCD.

An example of analysis of the appearance ratio of each tone in an image will now be described with reference to FIG. 2. A tone is also referred to as a hue. A tone diagram has twelve tones. Each of 1093 colors in the HUE & TONE system belongs to one of the tones. Thus, the colors of the pixels in an image, which has been color analyzed based on the HUE & TONE system, may be reclassified into the twelve tones. The appearance ratio of each tone in an image is indicated for each tone in the tone diagram. The tone diagram allows for instant recognition of the tones included in the building 1 and the scenery, as well as the most frequent tones.

An example of analysis of the appearance ratio of each color in an image scale will now be described with reference to FIG. 3. The image scale has a coordinate system in which colors are associated with impressions people have of the colors. In the image scale, colors that are perceived as “warm” are positioned toward the left side, colors that are perceived as “cool” are positioned toward the right side, colors that are perceived as “soft” are positioned toward the upper side, and colors that are perceived as “hard” are positioned toward the lower side. Specifically, each point in the coordinate system of the image scale is associated with a corresponding color of the HUE & TONE system in advance. Thus, the colors of the pixels in an image, which has been color analyzed based on the HUE & TONE system, may be positioned in the image scale. The image scale indicates the appearance ratio of each color. In addition, the image scale shows the positions of colors having relatively high appearance ratios. The positions of the colors having relatively high appearance ratios in the image scale allow for objective recognition of the impression of the landscape or the building in an image. Furthermore, the image scale allows for objective analysis of differences in impressions between multiple images. The appearance ratio of a certain color in an image is defined as (quantity of pixels of that color)×100/(total quantity of pixels in image).

In the image scale, the frequency of appearance of each color in an image is indicated by the size of the circle. For example, when a warm color appears in an image at a relatively high frequency, a relatively large circle is shown in the left-side area. When a cool color appears in an image at a relatively high frequency, a relatively large circle is shown in the right-side area. Such an image scale allows for instant recognition of the primary impression of the colors included in the building 1 and the scenery.

Numerous images are used for color analysis of the selected buildings and the selected scenery. According to the analysis of the numerous images of the selected buildings and the selected scenery, it has been found that the colors of the first display portions 11 and the colors of the second display portions 12 have relatively high appearance ratios in the selected buildings and the selected scenery. Therefore, the color range of the first display portions 11 and the color range of the second display portions 12 may be used for the exterior material 7 of the building 1 to create universal and timeless designs.

The operation of the present embodiment will now be described. The exterior material coordination tool 10 includes a plurality of first display portions 11 constituting a first lineup of chromatic colors, and a plurality of second display portions 12 constituting a second lineup of achromatic colors. An achromatic color includes a chromatic color having chroma of less than 0.8. The chroma of the colors of the first display portions 11 is in a range of 0.8 or greater and less than 3.5. In this manner, the colors shown by the first display portions 11 and the second display portions 12 are achromatic colors or chroma colors having relatively low chroma.

Achromatic colors often appear in the selected buildings and the selected scenery. Examples of an achromatic structure include a black-walled building 1, a white-walled building 1, gray roof tiles, a white-plastered wall, a black-painted plate wall, a retaining wall or a stone wall made of achromatic stones, such as limestones, or the like. Achromatic colors make the surrounding colors noticeable without being obstructive or boring, and are timeless. Also, achromatic colors make the greenery noticeable and are in harmony with the colors of the greenery that change in accordance with the four seasons throughout the year. In addition, achromatic colors are used for buildings 1 in any era and are not affected by trends.

Low chroma colors often appear in the selected buildings and the selected scenery. Examples of a low-chroma structure include an earthen-walled building 1, a wooden building 1, blue roof tiles, a retaining wall or a stone wall made of a low chroma stone material, such as granite, or the like. Low chroma colors make the surrounding colors noticeable without being obstructive or boring, and are timeless. Also, low chroma colors make the greenery noticeable and are in harmony with the colors of the greenery that change in accordance with the four seasons throughout the year. In addition, low chroma colors are subtle colors, and thus unlikely to become obstructive regardless of era or trends. Thus, even when a building adjacent to a low chroma building 1 is rebuilt or the greenery around the building 1 is replanted, the building 1 will blend into the surroundings. This maintains the harmony of the entire scenery including the building 1 and its surroundings. Furthermore, unlike achromatic colors, low chroma colors have tints. Such tints widen the color variation.

As described above, achromatic colors and low chroma colors are in harmony with the scenery of the country, and are unlikely to become awkward or old regardless of era or trends. The first lineup of chromatic colors and the second lineup of achromatic colors are arranged in the exterior material coordination tool 10 to enrich options of the client or the designer. In this manner, a color suitable for long-term use of the building 1 is proposed as the color of the exterior material 7.

The present embodiment has the following advantages.

(1) The exterior material coordination tool 10 includes the first display portions 11 constituting the first lineup of chromatic colors and the second display portions 12 constituting the second lineup of achromatic colors. An achromatic color includes a chromatic color having chroma of less than 0.8. The chroma of the colors of the first display portions 11 is in a range of 0.8 or greater and less than 3.5.

With this configuration, each of the colors shown by the first display portions 11 and the second display portions 12 in the exterior material coordination tool 10 is either an achromatic color or a chromatic color with low chroma. Achromatic colors and low chroma colors are commonly found in natural objects, such as wood or stone, and are thus in harmony with the scenery of the country and unlikely to become awkward or old regardless of era or trends. In this manner, a color suitable for long-term use of the building 1 is proposed as the color of the exterior material 7.

(2) The chroma of the colors of the first display portions 11 is in a range of 1.0 or greater and less than 1.5. With this configuration, since the chroma of the first display portions 11 is less than 1.5, the colors of the first display portions 11 aesthetically enhance the natural colors (hereinafter, “building surrounding natural colors”) around the building 1, such as green of the greenery, red or yellow of autumn leaves, or the like. The building surrounding natural colors are the colors that have always existed regardless of eras. The colors of the first display portions 11 aesthetically enhance such building surrounding natural colors. In this manner, a color suitable for long-term use of the building 1 is proposed as the color of the exterior material 7.

The second display portions 12 are achromatic. Achromatic colors aesthetically enhance the building surrounding natural colors. With the exterior material coordination tool 10 including the low chromatic first display portions 11 and the achromatic second display portions 12, a color suitable for long-term use of the building 1 can be proposed as the color of the exterior material 7 from the chromatic colors and the achromatic colors.

(3) The chroma of the colors of the first display portions 11 is in a range of 1.0 or greater and less than 1.5. Further, the hue of the colors of first display portions 11 may be in a range of 7.5 YR to 10 YR, inclusive, and 1.0 Y or greater and less than 5.0 Y in the Munsell color system. Such colors of the first display portions 11 aesthetically enhance the building surrounding natural colors, and are in harmony with the colors used in exterior materials 7 of buildings 1 that remain in the country across different eras. It can be said that buildings 1 that remain in a country across different eras have universal colors that blend into the landscape of the country. In this manner, a color suitable for long-term use of the building 1 is proposed as the color of the exterior material 7.

(4) The brightness of the colors of first display portions 11 and the brightness of the colors of second display portions 12 are in a range of 3.0 or greater and less than 9.0.

Natural colors of mountains, rivers, valleys, or oceans do not usually contain colors having a brightness that is lower than 3.0 in daylight. Further, natural colors of mountains, rivers, valleys, or oceans do not usually contain colors having a brightness that is higher than 9.0 in daylight. Since the brightness of the colors of the first display portions 11 and the brightness of the colors of the second display portions 12 are 3.0 or greater and less than 9.0, when the colors of the first display portions 11 or the colors of the second display portion 12 are adopted for the exterior material 7 of the building 1, there will not be discordance between the natural colors and the colors of the first display portions 11 and the colors of the second display portions 12. In this manner, a color suitable for long-term use of the building 1 is proposed as the color of the exterior material 7.

(5) The brightness of the colors of first display portions 11 and the brightness of the colors of second display portions 12 are in a range of 3.0 to 5.0, inclusive, or in a range of 6.0 or greater and less than 9.0.

In many cases, greenery is planted around the building 1. Also, the building 1 is built where vegetation can be seen, such as trees in mountains, crops in fields, trees along streets, trees and grass in parks, or the like. A typical value of the brightness of the greenery or the like (greenery and vegetation around the building 1) is approximately greater than 5.0 and less than 6.0 throughout the four seasons. When the brightness of the building 1 overlaps the brightness of the greenery or the like, even if the hue of the building 1 differs from the hue of the greenery or the like, the building 1 and the greenery or the like have the same color tone. Accordingly, the building 1 and the greenery or the like as a whole appear to lack variation. In this respect, the above configuration sets the first display portions 11 and the second display portions 12 to have different brightness from the greenery or the like.

Therefore, in a case in which the greenery or the like is arranged around the building 1, an appropriate color can be suggested such that the overall appearance including the building 1 and the greenery or the like will not be monotonous.

(6) The first display portions 11 and the second display portions 12 each belongs to any one of the multiple groups GR divided by brightness. The difference in brightness (brightness difference) between any one of the first display portions 11 and the second display portions 12 that belongs to one group GR and any one of the first display portions 11 and the second display portions 12 that belongs to another group GR is 1 or greater.

Specifically, when a certain group GR is selected, all the elements (first display portions 11 and second display portions 12) in that group GR has a brightness difference of 1 or greater from all elements in another group GR.

With this configuration, when selecting two colors from the exterior material coordination tool 10, two colors having a brightness difference of 1 or greater may be easily selected. For example, two distinctly different colors may be readily selected when designing a residential area of multiple buildings 1 or when using two colors for the external appearance of a single building 1. Specifically, when a single color is selected from each of two different groups GR, the difference in brightness of the two colors is 1 or greater. In this manner, two colors are easily selected.

In order to distinctly show the difference in color of two adjacent buildings 1, it is preferred that the difference in brightness of the colors of the two adjacent buildings 1 is 1.5 or greater. Also, when two colors are used in a single building 1, in order to distinctly show the difference in the two colors of the building 1, it is preferred that the difference in brightness of the two colors is 1.5 or greater. Even when selecting two colors having a brightness difference of 1.5 or greater, colors having a brightness difference of 1.5 or greater may be easily selected with the configuration described in advantage (6). For example, if one group GR including a first candidate color has a brightness difference of 1.0 from an adjacent group GR, the colors in the adjacent group GR are not selected and a color in another group GR differing from the adjacent group GR is selected. In this manner, the first candidate color and a color having a brightness difference of 1.5 or greater from the first candidate color can be easily selected.

A difference in brightness (brightness difference) of any one of the first display portions 11 and the second display portions 12 that belongs to one group GR and any one of the first display portions 11 and the second display portions 12 that belongs to another group GR may be 1.5 or greater.

(7) The first display portions 11 and the second display portions 12 are arranged on the base board 20. With this configuration, the exterior material coordination tool 10 may be hand-held. Therefore, the exterior material coordination tool 10 may be easily carried.

### Second Embodiment

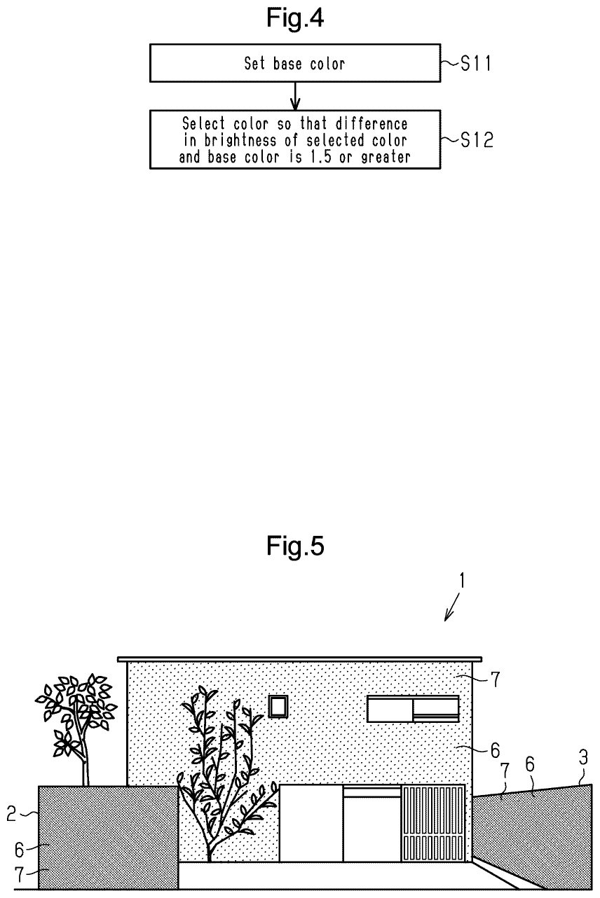

A method for selecting the color of the exterior material 7 of the building 1 will now be described with reference to FIGS. 4 to 6. The present embodiment describes a method for selecting the color of the exterior material 7 of the building 1 using the above-described exterior material coordination tool 10. The method for selecting the color of the exterior material 7 of the building 1 may be performed during consultation between a designer and a client.

As shown in FIG. 4, the method for selecting the color of the exterior material 7 includes a first step S11 and a second step S12.

In the first step S11, the designer sets a base color based on the color of a region where the building 1 is to be constructed. The base color is a color that is first set in the design of the building 1, or a color that is least likely to be changed in the design. In the first step S11, the color of the region is set as such a base color.

The color of the region is a color of a building material produced in the region, or a color of a building material used for the building 1 that serves as a landmark of the region. Examples of the building material produced in the region include stone. For example, Kugurizaka stone of Aomori Prefecture, Towada stone of Akita Prefecture, Oga stone of Akita Prefecture, Inai stone of Miyagi Prefecture, Shirakawa stone of Fukushima Prefecture, Ashino stone of Tochigi Prefecture, Oya stone of Tochigi Prefecture, Nakanojo stone of Gunma Prefecture, Suwa Teppei stone of Nagano Prefecture, Saku Teppei stone of Nagano Prefecture, Mino stone of Gifu Prefecture, Mikage stone of Hyogo Prefecture, Isahaya stone of Nagasaki Prefecture, Sakurajima lava stone of Kagoshima Prefecture, Ryukyu limestone of Okinawa Prefecture, or the like.

An example of the building 1 serving as a landmark of the region includes a brick warehouse in Otaru, Hokkaido. In this case, the building material used for the building 1 is bricks.

In the second step S12, the designer selects a color of the exterior material 7 from the first lineup or the second lineup, the color having a brightness difference of 1.5 or greater from the base color. The designer may suggest the selected color to the client.

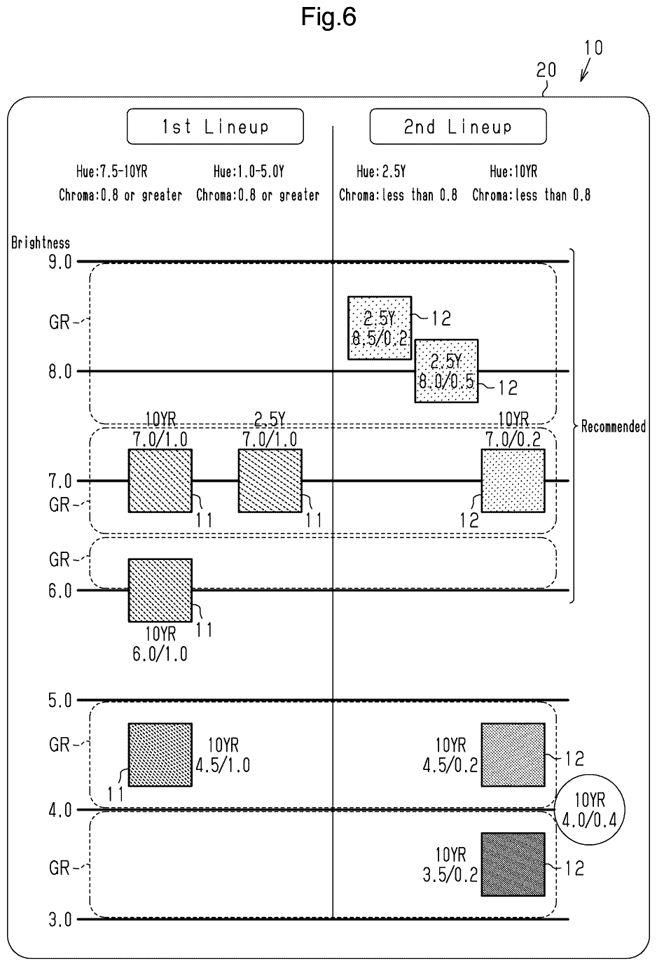

An example in which the building 1 is to be constructed in a stone production region or a region that was famous for stone production in the past will now be described with reference to FIGS. 5 and 6.

As shown in FIG. 5, in the first step S11, Suwa Teppei stones are set to be used on a gate wall 2 and a perimeter wall 3 in accordance with the preference of the client. Further, the color of Suwa Teppei stones may be determined from photo samples. Then, the selected color of the Suwa Teppei stones is identified. For example, the color is identified through comparison with color samples. The identified color is set as the base color of the building 1.

In the second step S12, the designer proposes the color of the exterior material 7 of the outer wall 6 of the building 1 using the exterior material coordination tool 10 for an exterior wall material of the building 1.

Specifically, as shown in FIG. 6, the position of the base color is shown in the exterior material coordination tool 10. The designer then recommends a range of colors that differ in brightness by 1.5 or greater. For example, in a case in which the color of Suwa Teppei stone is achromatic, blackish gray, and has a hue of 10 Y, brightness of 4.0, and chroma of 0.4, a color range having a brightness of 5.5 or greater is recommended as the color of the exterior material 7. The designer and the client may determine the color of the exterior material 7 in the recommended color range.

The above example has the following advantages. Locally produced stones are widely used in that region. When the stone material of the region where the building 1 is to be constructed is used, the building 1 readily harmonizes with the local landscape. In addition, the color of the exterior material 7 is selected from the colors (colors of first lineup and colors of second lineup) determined in advance as suitable for long-term use of the building 1. Therefore, the building 1 as a whole will be in harmony with the local landscape. Furthermore, the brightness of the color of the exterior material 7 selected in the second step S12 differs from the brightness of the base color by at least 1.5. Thus, the difference of the base color and the color of the exterior material 7 is visually distinct, so that the design of the building 1 as a whole will not be monotonous.

With the above-described method for selecting the color of the exterior material 7, when a color specific to the region where the building 1 is to be constructed is adopted for the building 1, another color suitable for long-term use of the building 1 can be selected as the color of the exterior material 7 without obscuring the color of the region.

### Third Embodiment

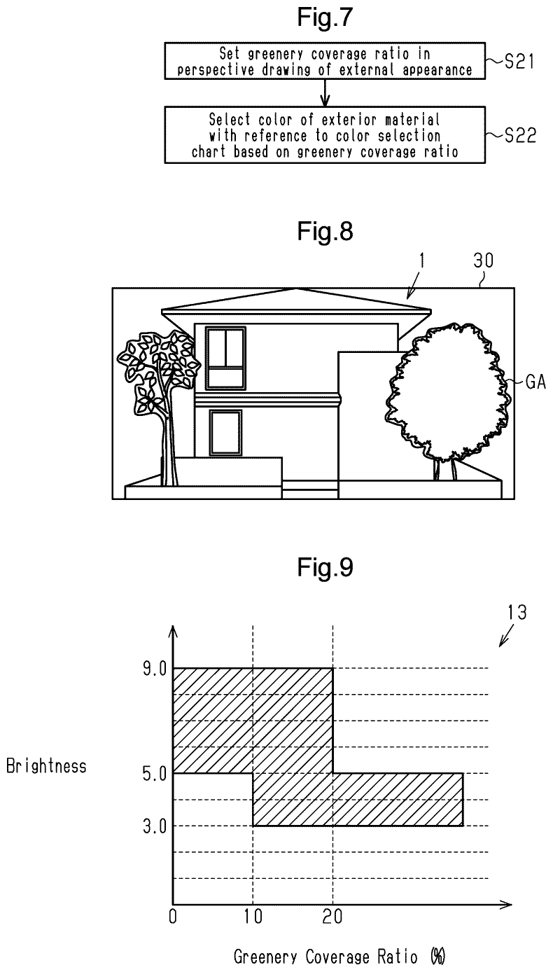

Another example of the method for selecting the color of the exterior material 7 of the building will now be described with reference to FIGS. 7 to 9. In the present embodiment, the color of the exterior material 7 of the building 1 is selected using the above-described exterior material coordination tool 10, in the same manner as in the second embodiment.

As shown in FIG. 7, the method for selecting the color of the exterior material 7 includes a first step S21 and a second step S22. In the first step S21, the designer sets a greenery coverage ratio in a perspective drawing of the external appearance of the building 1.

As shown in FIG. 8, the greenery coverage ratio is defined as a ratio of a greenery range GA in the perspective drawing of the external appearance. The perspective drawing of the external appearance has a rectangular frame 30. The frame 30 of the perspective drawing of the external appearance is sized to sufficiently include the building 1 and all the greenery on the premises of the building 1 in a front view of the building 1. The greenery coverage ratio is expressed by the following equation. Green coverage ratio =100 x area of greenery range GA/area of perspective drawing of the external appearance.

In the second step S22, the color of the exterior material 7 is selected from the first lineup or the second lineup with reference to a color selection chart 13 based on the greenery coverage ratio. The designer may suggest the selected color to the client.

The color selection chart 13 is a chart in which the brightness of the color increases as the greenery coverage ratio decreases. The color selection chart 13 indicates a brightness recommended for the color of the outer wall of the building 1 with respect to the greenery coverage ratio in the perspective drawing of the external appearance of the building 1.

FIG. 9 shows an example of the color selection chart 13. In this example, the horizontal axis represents the greenery coverage ratio. The vertical axis indicates the brightness of the color. A range indicated by the diagonal lines in the color selection chart 13 is a recommended brightness range. The color selection chart 13 is prepared based on the premise that the greenery increases the brightness of the entire building 1, and that the brightness of the entire building 1 has an appropriate range. Specifically, if the brightness of the entire building 1 is overly high, the building 1 becomes conspicuous against the colors of the background when the building 1 is viewed from outdoors. Accordingly, the building 1 will not be in harmony with the background. Also, if the brightness of the entire building 1 is overly low, the building 1 becomes blackish as a whole and creates a dark impression. Thus, the brightness of the entire building 1 has an appropriate range. Since the brightness of the greenery is around 5.0, a relatively high greenery coverage ratio has an effect of increasing the brightness of the entire building 1. Accordingly, in the color selection chart 13, the brightness of the recommended color becomes higher as the greenery coverage ratio becomes lower.

As described above, with the method for selecting the color of the exterior material 7 of the present example, the color of the exterior material 7 of the building 1 may be selected based on the greenery coverage ratio. Specifically, the color selection chart 13 in which the greenery coverage ratio is associated with the recommended brightness is used to select a color having an appropriate brightness in accordance with the greenery coverage ratio. This maintains the brightness of the entire building 1 within the appropriate range.

### Fourth Embodiment

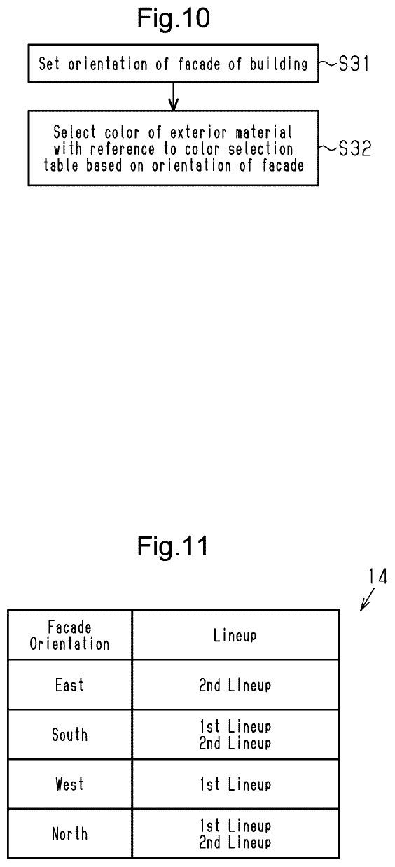

Another example of the method for selecting the color of the exterior material 7 of the building 1 will now be described with reference to FIGS. 10 to 12. In the present embodiment, the color of the exterior material 7 of the building 1 is selected using the above-described exterior material coordination tool 10, in the same manner as in the second embodiment.

As shown in FIG. 10, the method for selecting the color of exterior material 7 includes a first step S31 and a second step S32.

In the first step S31, the orientation of a facade of the building 1 is set. In many cases, a facade is a side of the building 1 facing the road. For example, a facade is a side including a front entrance.

In the second step S32, the color of the exterior material 7 is selected from the first lineup or the second lineup with reference to a color selection table 14 based on the orientation of the facade. The designer may suggest the selected color to the client.

The color selection table 14 will now be described with reference to FIG. 11. The color selection table 14 associates the orientation of the facade of the building 1 with colors recommended as the color of the outer wall 6 that forms the facade.

Specifically, in the color selection table 14, the orientation of the facade is associated with the lineups. The facade facing east is associated with the second lineup. The facade facing south is associated with the first and second lineups. The facade facing west is associated with the first lineup. The facade facing north is associated with the first and second lineups.

The building 1 looks beautiful at different times of the day depending on the orientation of the facade. For example, with an east-facing facade, the building 1 is aesthetically enhanced in the landscape in the morning when it is well lit by the sunlight. Morning light contains more blue light than evening light. Achromatic colors are aesthetically enhanced in bluish light. Thus, the second lineup is associated with the facade facing east. As a result, the aesthetic appearance of the building 1 is enhanced at the time of day when the building 1 is seen most clearly.

With an east-facing facade, the building 1 is aesthetically enhanced in the landscape in the evening when it is well lit by the sunlight. Evening light contains more red light than morning light. Chromatic colors look particularly appealing in reddish light. Thus, the first lineup is associated with the facade facing west. As a result, the aesthetic appearance of the building 1 is enhanced at the time of day when the building 1 is seen most clearly.

In the northern hemisphere, with a south-facing facade, the building 1 is aesthetically enhanced in the landscape at noon when it is well lit by the sunlight. Daytime light is stronger than morning and evening light. Thus, the first and second lineups are associated with the facade facing south. With a north-facing facade, the facade is in the shade during the day. Accordingly, there is no specific time of the day when the building 1 looks more aesthetically appealing than at other times of day. Thus, the first and second lineups are associated with the facade facing north. In the southern hemisphere, “south-facing” is replaced by “north-facing”, and “north-facing” is replaced by “south-facing”.

With the method for selecting the color of the exterior material 7, colors that enhance the aesthetic appearance of the building 1 at the time of day when the sun shines on the building 1 may be proposed.

### Examples of Using Two Colors

In the northern hemisphere, when the orientation of the facade of the building 1 is set to the north and two colors are adopted for the north-facing facade, the two colors may be selected from the first lineup and the second lineup so that the brightness difference is 2.0 or greater.

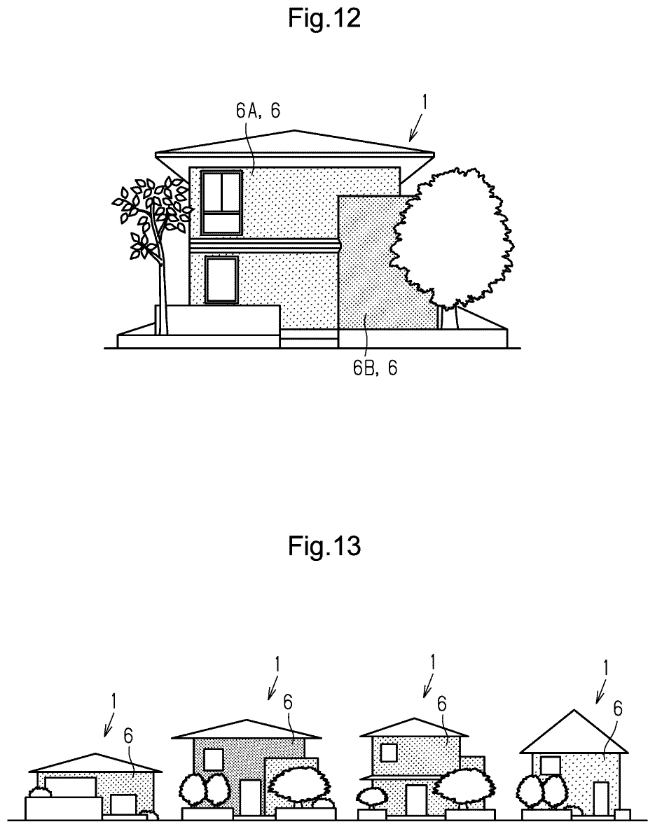

As shown in FIG. 12, the color of a first outer wall 6A on the first and second floors of the building 1 is set to, for example, a first color. In the building 1, the color of a second outer wall 6B extending from the first floor to a balcony on the second floor is set to a second color. In this case, the difference in brightness of the first and second colors is set to be 2.0 or greater.

With a north-facing facade, the facade is in the shade during the day. Accordingly, when two colors are used for the north-facing facade, it may be difficult to recognize the difference in the two colors. In this respect, the above configuration proposes two distinctly different colors for the north-facing facade. In the southern hemisphere, “north-facing” is replaced by “south-facing”.

### Fifth Embodiment

Another example of the method for selecting the color of the exterior material 7 of the building 1 will now be described with reference to FIG. 13. The present embodiment describes a color selection method for determining colors of multiple buildings 1 in the design of a row of houses that includes the buildings 1. For example, a residential area of subdivision housing may be designed as an example of a row of houses including multiple buildings 1. In such a case, if adjacent ones of the buildings 1 have colors that are similar in brightness, the residential area may create a monotonous impression. Accordingly, the exterior material coordination tool 10 is used to set the color of the exterior material 7 of each building 1, so that the colors of two adjacent exterior materials 7 differ in brightness by 1.5 or greater.

As shown in FIG. 13, for example, the color of the outer wall 6 of a certain building 1 is set so that the difference in brightness from the color of the outer wall 6 of an adjacent building 1 on the left is 1.5 or greater, and the difference in brightness from the color of the outer wall 6 of an adjacent building 1 on the right is 1.5 or greater. The colors of the buildings 1 arranged in the row are all selected in this manner. This contributes to a townscape that is rich in variation and yet tranquil.

Such a color selection method may also be used when constructing a new house (building 1) in a section of an existing residential area. Furthermore, such a color selection method may be used when renovating a house (building 1) in an existing residential area.

### Modified Examples

The above embodiments exemplify, without any intention to limit, applicable forms of the exterior material coordination tool 10 and the method for selecting the color of the exterior material 7 of the building 1. The exterior material coordination tool 10 and the method for selecting the color of the exterior material 7 of the building 1 may be modified from the embodiments described above. For example, the configurations of the above embodiments may be replaced, changed, or omitted in part or include additional elements. Modified examples of the above embodiments will now be described below.

(1) In the above embodiments, the first display portions 11 and the second display portions 12 are arranged on the base board 20. However, there is no limitation to such a configuration. For example, the first display portions 11 and the second display portions 12 of the exterior material coordination tool 10 may be shown on a display screen of an electronic device. The electronic device includes a device having a display screen, or a device capable of showing a display screen. Examples of the electronic device include a tablet, a personal computer, a smartphone, a projector, or the like. With this configuration, as compared to when the first display portion 11 and the second display portion 12 are printed, the colors will not be degraded by ultraviolet rays. The electronic device may include image software with an image enlargement function. In this case, the first display portions 11 and the second display portions 12 may be enlarged using the image software.

(2) In the second embodiment, three examples are described for the method for selecting the color of the exterior material 7 of the building 1. Two of the three examples may be combined. Alternatively, all of the three examples may be combined.

In an example, the color of the region where the building 1 is to be constructed may be set as the base color, and then the color of the exterior material 7 of the outer wall 6 may be selected based on the base color, the greenery coverage ratio, and the orientation of the facade of the building 1.

If there is no color of the region where the building 1 is to be constructed, the color of the exterior material 7 of the outer wall 6 may be selected based on the greenery coverage ratio and the orientation of the facade of the building 1 without setting the base color.

In a case of the building 1 without the greenery, the color of the region where the building 1 is to be constructed may be set as the base color, and then the color of the exterior material 7 of the outer wall 6 may be selected based on the base color and the orientation of the facade of the building 1.

If it is difficult to specify the main surface of the building 1, the color of the region where the building 1 is to be constructed may be set as the base color, and then the color of the exterior material 7 may be selected based on the base color and the greenery coverage ratio. The case in which it is difficult to specify the main surface of the building 1 includes, for example, a case in which the building 1 is in a corner lot such that both the front and side of the building 1 can be seen from the streets.

(3) The present technique may also be applied to a building in a country other than Japan. Specifically, the technique related to the exterior material coordination tool according to any one of clauses 4 to 10, which will be described later, may also be applied to a building in a country other than Japan. In this case, the exterior material coordination tool is for selecting a color of an exterior material of a building, and includes a plurality of first display portions constituting a first lineup of chromatic colors and a plurality of second display portions constituting a second lineup of achromatic colors. The values of the hue and chroma of the first display portions may be set in accordance with any region in the world. In addition, the technique related to the facade according to clauses 11 and 12 may be modified in accordance with any region in the world.

This specification discloses the following technique.

Clause 1

An exterior material coordination tool for selecting a color of an exterior material of a building, including:
first display portions constituting a first lineup of chromatic colors; and
second display portions constituting a second lineup of achromatic colors, in which
the first display portions show colors different from each other,
the second display portions show colors different from each other,
the achromatic colors include chromatic colors having chroma of less than 0.8, and
chroma of the colors of the first display portions is in a range of 0.8 or greater and less than 3.5.

Clause 2

The exterior material coordination tool according to clause 1, in which the chroma of the colors of the first display portions is in a range of 1.0 or greater and less than 1.5.

Clause 3

The exterior material coordination tool according to clause 2, in which hue of the colors of the first display portions is in a range of 7.5 YR to 10 YR, inclusive, and 1.0 Y or greater and less than 5.0 Y in the Munsell color system.

Clause 4

The exterior material coordination tool according to any one of clauses 1 to 3, in which brightness of the colors of the first display portions and brightness of the colors of the second display portions are in a range of 3.0 or greater and less than 9.0.

Clause 5

The exterior material coordination tool according to clause 4, in which the brightness of the colors of the first display portions and the brightness of the colors of the second display portions are in a range of 3.0 to 5.0, inclusive, or in a range of 6.0 or greater and less than 9.0.

### Clause 6

The exterior material coordination tool according to any one of clauses 1 to 5, in which
the first display portions and the second display portions each belong to any one of multiple groups divided by brightness, and
a difference in brightness between any one of the first display portions and the second display portions that belongs to one of the groups and any one of the first display portions and the second display portions that belongs to another one of the groups is 1 or greater.

Clause 7

The exterior material coordination tool according to any one of clauses 1 to 6, in which the first display portions and the second display portions are arranged on a base board.

Clause 8

The exterior material coordination tool according to any one of clauses 1 to 6, in which the first display portions and the second display portions are shown on a display screen of an electronic device.

### Clause 9

A method for selecting a color of an exterior material of a building using the exterior material coordination tool according to any one of clauses 1 to 8, the method including:
a first step of setting a base color based on a color of a region where the building is to be constructed; and
a second step of selecting a color of the exterior material from the first lineup or the second lineup, the color having a brightness difference of 1.5 or greater from the base color,
in which the color of the region is a color of a building material produced in the region or a color of a building material used for a building that serves as a landmark of the region.

### Clause 10

A method for selecting a color of an exterior material of a building using the exterior material coordination tool according to any one of clauses 1 to 8, the method including:
a first step of setting a greenery coverage ratio in a perspective drawing of an external appearance of the building; and
a second step of selecting a color of the exterior material from the first lineup or the second lineup with reference to a color selection chart based on the greenery coverage ratio,
in which the color selection chart is a chart in which brightness of the color increases as the greenery coverage ratio decreases.

### Clause 11

A method for selecting a color of an exterior material of a building using the exterior material coordination tool according to any one of clauses 1 to 8, the method including:
a first step of setting an orientation of a facade of the building; and
a second step of selecting a color of the exterior material from the first lineup or the second lineup with reference to a color selection table based on the orientation of the facade,
in which, in the color selection table,
   the facade facing east is associated with the second lineup,
   the facade facing south is associated with the first lineup and the second lineup,
   the facade facing west is associated with the first lineup, and the facade facing north is associated with the first lineup and the second lineup.

Clause 12

The method according to clause 11, in which:
when the orientation of the facade of the building is set to north in the northern hemisphere in the first step, and two colors are adopted for the facade facing north; or
when the orientation of the facade of the building is set to south in the southern hemisphere in the first step, and two colors are adopted for the facade facing south,
the second step includes selecting two colors from the first lineup and the second lineup so that a brightness difference is 2.0 or greater.

### REFERENCE SIGNS LIST

GA) greenery range, 1) building, 6) outer wall, 7) exterior material, 10) exterior material coordination tool, 11) first display portion, 12) second display portion, 13) color selection chart, 14) color selection table, 20) base board.

1. An exterior material coordination tool for selecting a color of an exterior material of a building, comprising:
first display portions constituting a first lineup of chromatic colors; and
second display portions constituting a second lineup of achromatic colors, wherein
the first display portions show colors different from each other,
the second display portions show colors different from each other,
the achromatic colors include chromatic colors having chroma of less than 0.8, and
chroma of the colors of the first display portions is in a range of 0.8 or greater and less than 3.5.

2. The exterior material coordination tool according to claim 1, wherein the chroma of the colors of the first display portions is in a range of 1.0 or greater and less than 1.5.

3. The exterior material coordination tool according to claim 2, wherein hue of the colors of the first display portions is in a range of 7.5 YR to 10 YR, inclusive, and 1.0 Y or greater and less than 5.0 Y in the Munsell color system.

4. The exterior material coordination tool according to claim 1, wherein brightness of the colors of the first display portions and brightness of the colors of the second display portions are in a range of 3.0 or greater and less than 9.0.

5. The exterior material coordination tool according to claim 4, wherein the brightness of the colors of the first display portions and the brightness of the colors of the second display portions are in a range of 3.0 to 5.0, inclusive, or in a range of 6.0 or greater and less than 9.0.

6. The exterior material coordination tool according to claim 1, wherein
the first display portions and the second display portions each belong to any one of multiple groups divided by brightness, and
a difference in brightness between any one of the first display portions and the second display portions that belongs to one of the groups and any one of the first display portions and the second display portions that belongs to another one of the groups is 1 or greater.

7. The exterior material coordination tool according to claim 1, wherein the first display portions and the second display portions are arranged on a base board.

8. The exterior material coordination tool according to claim 1, wherein the first display portions and the second display portions are shown on a display screen of an electronic device.

9. A method for selecting a color of an exterior material of a building using the exterior material coordination tool according to claim 1, the method comprising:
setting a base color based on a color of a region where the building is to be constructed; and
selecting a color of the exterior material from the first lineup or the second lineup, the color having a brightness difference of 1.5 or greater from the base color,
wherein the color of the region is a color of a building material produced in the region or a color of a building material used for a building that serves as a landmark of the region.

10. A method for selecting a color of an exterior material of a building using the exterior material coordination tool according to claim 1, the method comprising:
setting a greenery coverage ratio in a perspective drawing of an external appearance of the building; and
selecting a color of the exterior material from the first lineup or the second lineup with reference to a color selection chart based on the greenery coverage ratio,
wherein the color selection chart is a chart in which brightness of the color increases as the greenery coverage ratio decreases.

11. A method for selecting a color of an exterior material of a building using the exterior material coordination tool according to claim 1, the method comprising:
setting an orientation of a facade of the building; and
selecting a color of the exterior material from the first lineup or the second lineup with reference to a color selection table based on the orientation of the facade,
wherein, in the color selection table,
the facade facing east is associated with the second lineup,
the facade facing south is associated with the first lineup and the second lineup,
the facade facing west is associated with the first lineup, and
the facade facing north is associated with the first lineup and the second lineup.

12. The method according to claim 11, wherein:
when the orientation of the facade of the building is set to north in the northern hemisphere in the setting the orientation of the facade, and two colors are adopted for the facade facing north; or
when the orientation of the facade of the building is set to south in the southern hemisphere in the setting the orientation of the facade, and two colors are adopted for the facade facing south,
the selecting the color of the exterior material includes selecting two colors from the first lineup and the second lineup so that a brightness difference is 2.0 or greater.
